(19) United States
(12) Patent Application Publication
(10) Pub. No.: US 2020/0027899 A1
(43) Pub. Date: Jan. 23, 2020

(54) ARRAY SUBSTRATE, DISPLAY PANEL AND MANUFACTURING METHOD OF THE ARRAY SUBSTRATE

(71) Applicant: WUHAN CHINA STAR OPTOELECTRONICS TECHNOLOGY CO., LTD., Wuhan, Hubei (CN)

(72) Inventor: Chen CHEN, Shenzhen (CN)

(73) Assignee: Wuhan China Star Optoelectronics Technology Co., Ltd., Wuhan, Hubei (CN)

(21) Appl. No.: 15/744,298

(22) PCT Filed: Oct. 20, 2017
(86) PCT No.: PCT/CN2017/107149

§ 371 Date: Oct. 10, 2018

(30) Foreign Application Priority Data
Jul. 25, 2017 (CN) 201710613991.4

(51) Int. Cl. H01L 27/12; G02F 1/1337; G02F 1/1368; G02F 1/1362

(52) U.S. Cl. CPC H01L 27/124; G02F 1/133707; G02F 1/136286; G02F 1/1368; H01L 27/1259

(57) ABSTRACT

The present disclosure provides an array substrate, a display panel and a manufacturing method of the array substrate, and the array substrate comprises a gate line, a thin film transistor (TFT), a passivation layer and a pixel electrode; wherein the gate line is electrically connected to a gate electrode of the thin film transistor, the pixel electrode is electrically connected to a drain electrode of the thin film transistor, the passivation layer is located between a layer where the thin film transistor is located and a layer where the pixel electrode is located, the passivation layer has a thickness gradually changed along an extending direction of the gate line. The present disclosure can improve the uniformity of displayed images by the above array substrate.

### CROSS-REFERENCE TO RELATED APPLICATIONS

The present application is a 35 U.S.C. § 371 National Phase conversion of International (PCT) Patent Application No. PCT/CN2017/107149 filed Oct. 20, 2017, which claims foreign priority to Chinese Patent Application No. 201710613991.4, filed on Jul. 25, 2017 in the State Intellectual Property Office of China, the entire contents of which are hereby incorporated by reference.

### TECHNICAL FIELD

Embodiments of the present disclosure generally relate to display technology, and in particular relate to an array substrate, a display panel and a manufacturing method of the array substrate.

### BACKGROUND

Liquid crystal display (LCD) panel has the advantages of a low voltage, a micro power consumption, a large amount of display information and an easy colorization. It occupies the leading position in the current display market and has been widely used in electronic computers, electronic notebooks, mobile phones, video cameras, HDTV and other electronic equipments.

When the liquid crystal display panel is displayed, frames are switched by means of scanning the gate line.

The inventor of the present disclosure has found in the long-term research that the conventional display panel displays unevenness, and some parts of the displayed images are bright, and some parts thereof are dark.

### SUMMARY

The present disclosure provides an array substrate, a display panel and a manufacturing method of the array substrate to solve technical problems, which can improve the uniformity of displayed images.

In order to solve the above-mentioned problems, a technical scheme adopted by the present disclosure is to provide an array substrate comprising a gate line, a thin film transistor (TFT), a passivation layer and a pixel electrode; wherein the gate line is electrically connected to a gate electrode of the thin film transistor, the pixel electrode is electrically connected to a drain electrode of the thin film transistor, the passivation layer is located between a layer where the thin film transistor is located and a layer where the pixel electrode is located, the passivation layer has a thickness gradually decreased along an extending direction of the gate line, and the passivation layer is made of a material selected from a group consisted of at least one of silicon nitride and silicon oxide.

Another technical scheme adopted by the present disclosure is to provide a display panel comprising an array substrate comprises a gate line, a thin film transistor (TFT), a passivation layer and a pixel electrode, wherein the gate line is electrically connected to a gate electrode of the thin film transistor, the pixel electrode is electrically connected to a drain electrode of the thin film transistor, the passivation layer is located between a layer where the thin film transistor is located and a layer where the pixel electrode is located, and the passivation layer has a thickness gradually changed along a direction of a signal outputted from the gate line.

Another technical scheme still adopted by the present disclosure is to provide a manufacturing method of an array substrate, which comprises: providing a substrate; forming a gate line, a thin film transistor, a passivation layer and a pixel electrode on the substrate in sequence; wherein the gate line is electrically connected to a gate electrode of the thin film transistor, the pixel electrode is electrically connected to a drain electrode of the thin film transistor, the passivation layer is located between a layer where the thin film transistor is located and a layer where the pixel electrode is located, and the passivation layer has a thickness gradually changed along an extending direction of the gate line.

Compared with the prior art, the thickness of the passivation layer between the layer of the thin film transistor and the layer of the pixel electrode can be gradually changed along the extending direction of the gate line which can improve the uniformity of the displayed images.

### BRIEF DESCRIPTION OF THE DRAWINGS

In order to illustrate the technical schemes in the embodiments of the present disclosure more clearly, the accompanying drawings to be used in the description of the examples will be briefly described below. It is obviously that the accompanying drawings in the following description are merely some embodiments of the present disclosure, and for those ordinary skilled in the art , which may obtains other accompanying drawings according to these accompanying drawings without departing from the creative work, wherein:

FIG. 1 is a schematic diagram of an array substrate in top view according to an embodiment of the present disclosure.

FIG. 2 is a schematic diagram of an array substrate in A-B direction.

FIG. 3 is a schematic diagram of a display panel according to an embodiment of the present disclosure.

FIG. 4 is a flow chart of a manufacturing method of an array substrate according to an embodiment of the present disclosure.

FIG. 5 is a flow chart of a manufacturing method of an array substrate according to another part of embodiments of the present disclosure.

FIG. 6 is a schematic diagram of an array substrate according to blocks S4021 to S4024.

### DETAILED DESCRIPTION

The technical schemes described in the embodiments of the present disclosure will now be described clearly and completely in conjunction with the accompanying drawings in the embodiments of the present disclosure. Apparently, the described embodiments are only part of the embodiments of the disclosure and are not intended to be exhaustive. All of other embodiments obtained by those ordinary skilled in the art based on embodiments in the present disclosure without making creative work are within the scope of the present disclosure.

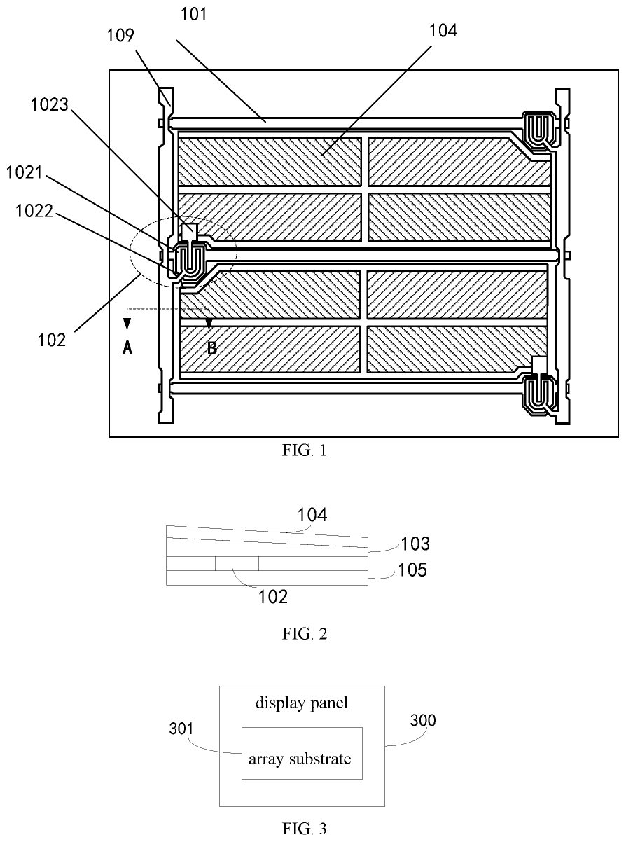

Referring to FIG. 1 and FIG. 2, FIG. 1 is a schematic diagram of an array substrate in top view according to an embodiment of the present disclosure, and FIG. 2 is a schematic diagram of an array substrate in A-B direction.

The array substrate comprises a gate line 101, a thin film transistor (TFT) 102, a passivation layer 103 and a pixel electrode 104, optionally, the array substrate further comprises a data line 109.

In one embodiment, the thin film transistor 102 comprises a gate electrode 1021, a source electrode 1022, and a drain electrode 1023. Optionally, the gate line 101 and the gate electrode 1021 are made of metal in the same layer. The gate line 101 can be electrically connected to the gate electrode 1021, and the pixel electrode 104 can be electrically connected to the drain electrode 1023. When the displayed images are required, the gate line 101 can be input a scan signal to the gate electrode 1021 to turn on the thin film transistor 102. Then, a data signal is inputted to the source electrode 1022 from the data line 109, and then the data signal is inputted to the pixel electrode 104 through the drain electrode 1023.

The passivation layer 103 may be located between a layer where the thin film transistor 120 is located and a layer where the pixel electrode 104 is located, the passivation layer 103 may have a thickness gradually changed along an extending direction of the gate line 101, that is, for the passivation layer 103, the thickness of different location may not be exactly the same. It can be known from a calculation formula of capacitance

$$C = \frac{ɛ S}{4 π k d} ↵$$

(d is distance between plates) that along the extending direction of the gate line 101, when the passivation layer 103 has a thickness gradually changed along an extending direction of the gate line 101, a storage capacity Cs may be also gradually changed. Specifically, as the thickness of the passivation layer 103 is larger, the storage capacity may be smaller, and as the thickness of the passivation layer 103 is smaller, the storage capacity may be larger.

A pressure drop formula

$$Δ {V}_{p} = \frac{{C}_{gs}}{{C}_{gs} + {C}_{lc} + {C}_{s}} * {V}_{ghl} ↵$$

(ΔVp is a pressure drop value, Cs is the storage capacity) shows that with gradual change of storage capacity, the pressure drop value may be gradually changed, specifically, as the storage capacity is larger, the pressure drop value may be smaller, and as the storage capacity is smaller, the pressure drop value may be larger.

Therefore, the passivation layer 103 may have the thickness gradually changed along an extending direction of the gate line 101, the voltage drop value may also be gradually changed. Specifically, as the thickness of the passivation layer 103 is larger, the voltage drop value may be larger, and as the thickness of the passivation layer 103 is smaller, the voltage drop value may be smaller, that is, the thickness of the passivation layer 103 can be proportional to the voltage drop value.

Therefore, in this embodiment, the passivation layer 103 may have the thickness gradually changed along the extending direction of the gate line 101, that is, the voltage drop value can be adjusted by adjusting the thickness of the passivation layer 103. For example, when the voltage drop value is too high and the displayed image are dark, the voltage drop value can be reduced by reducing the thickness of the passivation layer 103 to improve the uniformity of the display panel.

In the above embodiment, the thickness of the passivation layer 103 between the layer of the thin film transistor 102 and the layer of the pixel electrode 104 may be gradually changed along the extending direction of the gate line 101 which can improve the uniformity of the displayed images.

As shown in FIG. 2, in one application scenario of the above embodiment, the passivation layer 103 may have the thickness gradually decreased along the extending direction of the gate line 101, that is, farther the distance from the input signal terminal of the gate line 101 is, smaller the thickness of the passivation layer 103 may be.

In the prior art, as the transmission distance of the passivation layer 103 is increased, the signal can be gradually weakened, and as the transmission distance is from near to far, the voltage drop value may be gradually increased and the display images may gradually be dark. Therefore, in this application scenario, the passivation layer 103 may have thickness gradually decreased along the extension direction of the gate line 101, and as the thickness of the passivation layer 103 can be gradually decreased, the voltage drop value may also be gradually decreased, so that the display images may not be dim along the extending direction of the gate line 103 and the uniformity of the display images can be improved.

Optionally, in this embodiment, a via hole (the via hole is not shown in the figure) can be provided with the passivation layer 103, and the pixel electrode 104 can be electrically connected to the drain electrode 1023 through the via hole.

Optionally, in this embodiment, the passivation layer 103 may be make of at least one of silicon nitride and silicon oxide. Of course, in other embodiments, the passivation layer 103 may be make of other organic or inorganic material.

Optionally, in this embodiment, the array substrate further comprises a base substrate 105 which may have an excellent optical performance, a high transparency and a low reflectivity, for example, the array substrate may be made of glass material.

Referring to FIG. 3, FIG. 3 is a schematic diagram of a display panel according to an embodiment of the present disclosure. The display panel 300 comprises an array substrate 301 which can be the array substrate in any one of the above embodiments. The specific structure can be referred to the above and will not be repeated here.

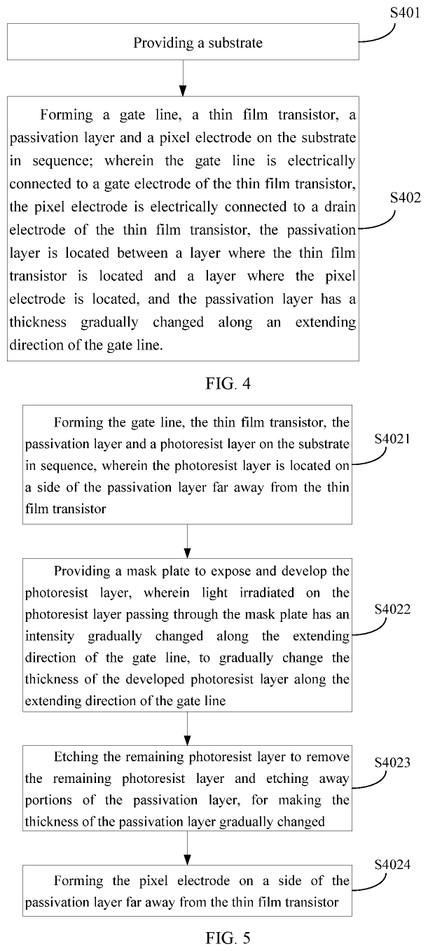

Referring to FIG. 4, FIG. 4 is a flow chart of a manufacturing method of an array substrate according to an embodiment of the present disclosure.

The method is described in detail below with reference to FIG. 1 and FIG. 2, the method comprises:

S401: a substrate 105 is provided.

The substrate 105 may have an excellent optical performance, a high transparency and a low reflectivity, for example, the array substrate may be made of glass material.

S402: a gate line 101, a thin film transistor 102, a passivation layer 103 and a pixel electrode 104 is formed on the substrate in sequence; wherein the gate line 101 is electrically connected to a gate electrode 1021 of the thin film transistor 101, the pixel electrode 104 is electrically connected to a drain electrode 1023 of the thin film transistor 102, the passivation layer is located between a layer where the thin film transistor 102 is located and a layer of the pixel electrode 104 is located, and the passivation layer 103 has a thickness gradually changed along an extending direction of the gate line 101.

In this embodiment, the thickness of the passivation layer 103 may have the thickness gradually changed along the extending direction of the gate line 101, that is, the voltage drop value can be adjusted by adjusting the thickness of the passivation layer 103. When it is required to decrease the brightness for the high brightness of the screen images, the passivation layer 101 may have the thickness increased to increase the voltage drop value, and when it is required to increase the brightness for the darkness of the screen display, the thickness of the passivation layer 101 can be decreased to decrease the voltage drop value.

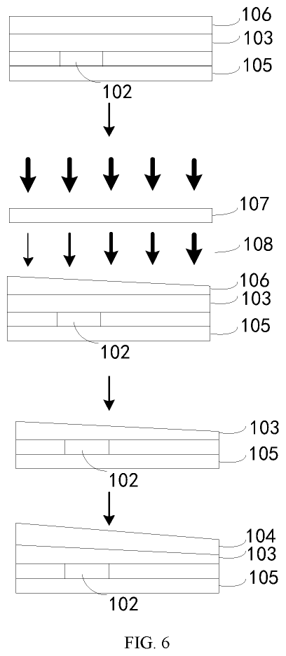

Referring to FIG. 5 and FIG. 6, FIG. 5 is a flow chart of a manufacturing method of an array substrate according to another part of embodiments of the present disclosure, and FIG. 6 is a schematic diagram of an array substrate according to blocks S4021 to S4024.

S4021: the gate line 101, the thin film transistor 102, the passivation layer 103 and a photoresist layer 106 is formed on the substrate 105 in sequence, wherein the photoresist layer 106 is located on a side of the passivation layer 103 far away from the thin film transistor 102, that is, the photoresist layer 106 is covered the passivation layer 103.

S4022: a mask plate 107 to exposing and developing the photoresist layer 106 is provided, wherein light 108 irradiated on the photoresist layer 106 passing through the mask plate 107 has an intensity gradually changed along the extending direction of the gate line 101, to gradually change the thickness of the developed photoresist layer 106 along the extending direction of the gate line 101.

Optionally, in this embodiment, a light transmittance of the mask plate 107 may be gradually changed along the extending direction of the gate line 101, so that the light 108 irradiated to the photoresist layer 106 through the mask plate 107 can be gradually changed. In other embodiments, the light transmittance of the mask plate 107 may not be gradually changed along the extending direction of the gate line 101, that is, the light transmittance of the mask plate 107 can be consistent, and by changing the amount of light irradiated on the mask plate 107, the light 108 passed through the mask plate 107 can be gradually changed.

S4023: the remaining photoresist layer 106 to remove the remaining photoresist layer 106 is etched and portions of the passivation layer 103 is etched away, for making the thickness of the passivation layer 103 can be gradually changed.

During the etching process, the remaining photoresist layer 106 can be etched, but in a same period of time, a region with a thin photoresist can be preferentially etched, so that the passivation layer 103 corresponding to the region can be etched, and the passivation layer 103 corresponding to the thick resist area cannot be etched due to the photoresist is not etched, so that the thickness of the passivation layer 103 can be gradually changed after the etching is completed.

S4024: the pixel electrode is formed on a side of the passivation layer far away from the thin film transistor.

The pixel electrode 104 can be formed on a side of the passivation layer 103 far away from the thin film transistor 102. That is, the pixel electrode 104 can be covered the passivation layer 103. Optionally, the pixel electrode 104 can be made of indium tin oxide (ITO).

Optionally, in any one of the foregoing manufacturing methods of the array substrate, the passivation layer 103 may have the thickness gradually decreased along the extension direction of the gate line 101, so that the display images may not be dim along the extending direction of the gate line 103 and the uniformity of the display images can be improved.

The array substrate manufactured by the manufacturing method of any one of the array substrates described above is the array substrate in any one of the above embodiments. For a specific array substrate structure, reference may be made to the above description, which is not described herein again.

The above-mentioned is merely an embodiment of the present disclosure and is not intended to limit the scope of the invention, and any equivalent structure or equivalent process transformation using the present specification and the accompanying drawings directly or indirectly applied in other related technical fields are included within the scope of the patent protection of the present disclosure.

1. An array substrate, comprising:
a gate line, a thin film transistor (TFT), a passivation layer formed of a material selected from a group consisting of silicon nitride and silicon oxide, and a pixel electrode;
wherein the gate line is electrically connected to a gate electrode of the TFT, the pixel electrode is electrically connected to a drain electrode of the TFT, the passivation layer is located between a first layer where the TFT is located and a second layer where the pixel electrode is located, and the passivation layer has a gradually decreasing thickness in a direction defined by an extension of the gate line of the gate electrode of the corresponding TFT.

2. The array substrate of claim 1, wherein the passivation layer is provided with a via, and the pixel electrode is electrically connected to the drain electrode of the TFT through the via.

3. The array substrate of claim 1, wherein the pixel electrode is made of indium tin oxide (ITO).

4. A display panel, comprising:
an array substrate comprises a gate line, a thin film transistor (TFT), a passivation layer formed of a material selected from a group consisting of silicon nitride and silicon oxide, and a pixel electrode, wherein the gate line is electrically connected to a gate electrode of the TFT, the pixel electrode is electrically connected to a drain electrode of the TFT, the passivation layer is located between a first layer where the TFT is located and a second layer where the pixel electrode is located, and the passivation layer has a gradually changing thickness in a direction defined by the gate line.

5. The display panel of claim 4, wherein the thickness of the passivation layer gradually decreases along the direction defined by the gate line.

6. The display panel of claim 4, wherein the passivation layer is provided with a via, and the pixel electrode is electrically connected with the drain electrode of the TFT through the via.

7. (canceled)

8. The display panel of claim 4, wherein the pixel electrode is made of indium tin oxide (ITO).

9. A manufacturing method of an array substrate, comprising:
providing a substrate;
forming a gate line, a thin film transistor, a passivation layer formed of a material selected from a group consisting of silicon nitride and silicon oxide and a pixel electrode on the substrate in sequence;
wherein the gate line is electrically connected to a gate electrode of the thin film transistor, the pixel electrode is electrically connected to a drain electrode of the thin film transistor, the passivation layer is located between a first layer where the thin film transistor is located and a second layer where the pixel electrode is located, and the passivation layer has a gradually changing thickness in a direction defined by an extension of the gate line of the gate electrode of the corresponding thin film transistor.

10. The method of claim 9, wherein the step of forming a gate line, a thin film transistor, a passivation layer formed of a material selected from a group consisting of silicon nitride and silicon oxide and a pixel electrode on the substrate in sequence, comprises:
forming the gate line, the thin film transistor, the passivation layer and a photoresist layer on the substrate in sequence, wherein the photoresist layer is located on a side of the passivation layer far away from the thin film transistor;
providing a mask plate to expose and develop the photoresist layer, wherein light irradiated on the photoresist layer passing through the mask plate has an intensity gradually changing in the direction defined by the extension of the gate line in order to gradually change the thickness of the photoresist layer in the direction defined by the extension of the gate line;
etching a remaining photoresist layer to remove the remaining photoresist layer and etching away portions of the passivation layer to make the thickness of the passivation layer gradually changing in the direction defined by the extension of the gate line.
forming the pixel electrode on the side of the passivation layer far away from the thin film transistor.

11. The method of claim 9, wherein the thickness of the passivation layer gradually decreases in the direction defined by the extension of the gate line.

12. (canceled)

13. The method of claim 9, wherein the pixel electrode is made of indium tin oxide (ITO).
